(19) United States
(12) Patent Application Publication
(10) Pub. No.: US 2025/0366330 A1
(43) Pub. Date: Nov. 27, 2025

(54) DISPLAY DEVICE

(71) Applicant: Samsung Display Co., Ltd., Yongin-si (KR)

(72) Inventor: Chun Gi YOU, Yongin-si (KR)

(21) Appl. No.: 19/183,506

(22) Filed: Apr. 18, 2025

(30) Foreign Application Priority Data
May 23, 2024 (KR) 10-2024-0067164

(51) Int. Cl. H10K 59/131; H10K 50/19; H10K 59/122; H10K 59/80

(52) U.S. Cl. CPC H10K 59/131; H10K 50/19; H10K 59/122; H10K 59/80516

(57) ABSTRACT

A display device includes a base layer; a reflective electrode on the base layer; a planarization layer over the reflective electrode, the planarization layer having a flat top surface; an anode electrode on the planarization layer; a pixel defining layer on a portion of the anode electrode and the planarization layer; a light emitting structure on the anode electrode and the pixel defining layer; a cathode electrode on the light emitting structure; and a metal layer overlapping with the portion of the anode electrode and the pixel defining layer, wherein the planarization layer includes a penetration hole connecting the anode electrode and the reflective electrode to each other, wherein the metal layer includes a first portion overlapping with the penetration hole and a second portion not overlapping with the penetration hole, and wherein the first portion is between the anode electrode and the pixel defining layer.

### CROSS-REFERENCE TO RELATED APPLICATION

The present application claims priority to and the benefit of Korean patent application No. 10-2024-0067164, filed on May 23, 2024, in the Korean Intellectual Property Office, the entire disclosure of which is incorporated herein by reference.

### BACKGROUND

### 1. Field

Aspects of the present disclosure generally relates to a display device.

### 2. Description of the Related Art

Recently, as interest in information displays is increased, research and development of display devices have been continuously conducted.

In particular, an organic light emitting diode (OLED) is an active light emitting display element, and has not only advantages of having a wide viewing angle and being excellent in contrast but also advantages of being able to be driven at a low voltage, being lightweight and thin, and having a high response speed. Hence, the OLED has come into the spotlight as a next-generation display element.

The above information disclosed in this Related Art section is only for enhancement of understanding of the background of the disclosure and therefore it may contain information that does not form the prior art that is already known in this country to a person of ordinary skill in the art.

### SUMMARY

Aspects of embodiments of the present disclosure are directed to a display device having improved efficiency. For example, in the display device, at least one metal layer is disposed in an area in which step difference portions of a pixel defining layer overlap with each other, so that light emitted from the step difference portions of the pixel defining layer can be more effectively blocked.

According to some embodiments of the present disclosure, there is provided a display device including: a base layer; a reflective electrode on the base layer; a planarization layer over the reflective electrode, the planarization layer having a flat top surface; an anode electrode on the planarization layer; a pixel defining layer on a portion of the anode electrode and the planarization layer; a light emitting structure on the anode electrode and the pixel defining layer; a cathode electrode on the light emitting structure; and a metal layer overlapping with the portion of the anode electrode and the pixel defining layer, wherein the planarization layer includes a penetration hole connecting the anode electrode and the reflective electrode to each other, wherein the metal layer includes a first portion overlapping with the penetration hole and a second portion not overlapping with the penetration hole, and wherein the first portion is between the anode electrode and the pixel defining layer.

In some embodiments, the first portion is in contact with a top surface of the anode electrode that is adjacent to the cathode electrode.

In some embodiments, the second portion is between the anode electrode and the pixel defining layer.

In some embodiments, the second portion is in contact with a top surface of the anode electrode that is adjacent to the cathode electrode.

In some embodiments, the pixel defining layer includes a plurality of insulating layers, and the second portion is between the anode electrode and one of the plurality of insulating layers that is adjacent to the planarization layer.

In some embodiments, the second portion has a width narrower than a width of a first area in which the insulating layer and the anode electrode overlap with each other.

In some embodiments, the pixel defining layer includes a plurality of insulating layers, and the first portion is between the anode electrode and one of the plurality of insulating layers that is adjacent to the planarization layer.

In some embodiments, the first portion has a width narrower than a width of a second area in which the insulating layer and the anode electrode overlap with each other.

In some embodiments, the first portion has a width wider than a width of the penetration hole.

In some embodiments, the metal layer includes: a first metal layer spaced apart from the base layer by a first distance; and a second metal layer spaced apart from the base layer by a second distance different from the first distance, and wherein the first metal layer is provided as the first portion, and wherein the second metal layer is provided as the second portion.

In some embodiments, the second portion is between the anode electrode and the reflective electrode.

In some embodiments, the second portion is in contact with the reflective electrode.

In some embodiments, the second portion is positioned to face the anode electrode with the planarization layer interposed therebetween.

In some embodiments, the second portion has a width narrower than a width of a first area in which the portion of the anode electrode and the pixel defining layer overlap with each other.

In some embodiments, the first and second portions include a conductive material.

In some embodiments, the light emitting structure includes at least two light emitting units that are sequentially stacked and at least one charge generation layer between the light emitting units, and each of the at least two light emitting units includes a light emitting layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. Like reference numerals refer to like elements throughout.

FIG. 1 is a block diagram illustrating a display device according to some embodiments of the present disclosure.

FIG. 2 is a block diagram illustrating one of the sub-pixels shown in FIG. 1, according to some embodiments of the present disclosure.

FIG. 3 is a circuit diagram illustrating the sub-pixel shown in FIG. 2, according to some embodiments of the present disclosure.

FIG. 4 is a plan view illustrating a display panel shown in FIG. 1, according to some embodiments of the present disclosure.

FIG. 5 is an exploded perspective view illustrating a portion of the display panel shown in FIG. 4, according to some embodiments of the present disclosure.

FIG. 6 is a plan view illustrating one of the pixels shown in FIG. 5, according to some embodiments of the present disclosure.

FIG. 7 is a sectional view taken along the line I-I′ shown in FIG. 3, according to some embodiments of the present disclosure.

FIGS. 8 and 9 are enlarged view illustrating the portion A shown in FIG. 7, according to some embodiments of the present disclosure.

FIGS. 10 and 11 are sectional views illustrating a light emitting structure included in any one of first to third light emitting elements shown in FIG. 6, according to some embodiments of the present disclosure.

FIGS. 12 and 13 are plan views illustrating one of the pixels shown in FIG. 4, according to some embodiments of the present disclosure.

### DETAILED DESCRIPTION

Hereinafter, some embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

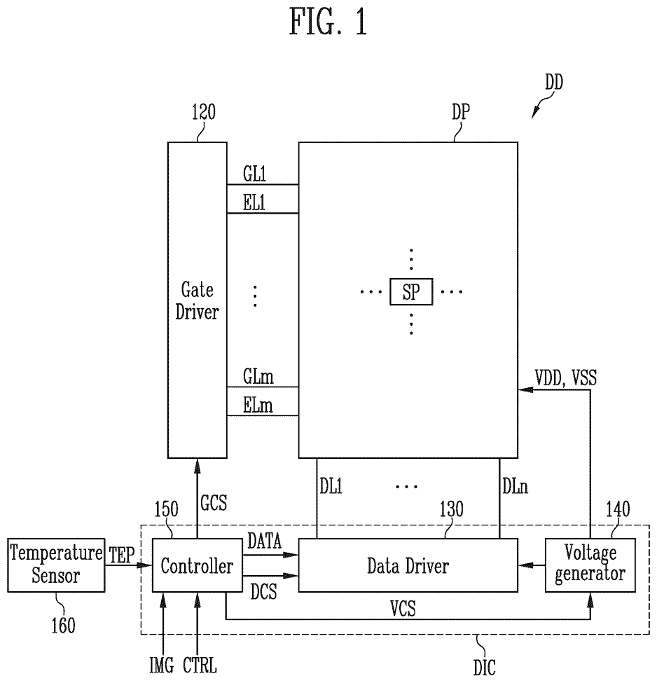

FIG. 1 is a block diagram illustrating a display device according to some embodiments of the present disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel. For example, three sub-pixels SP may constitute one pixel.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In some embodiments, the gate control signal GCS may include a start signal indicating a start of each frame, a horizontal synchronization signal for outputting gate signals in synchronization with timings at which data signals are applied, and the like.

In some embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be disposed at one side of the display panel DP. However, embodiments of the present disclosure are not limited thereto. For example, the gate driver 120 may be divided into two or more drivers which are physically and/or logically divided, and these drivers may be disposed at one side of the display panel DP and the other side of the display panel DP, which is opposite to the one side. As such, in some embodiments, the gate driver 120 may be disposed in various suitable forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLm. Accordingly, corresponding sub-pixels SP may generate light corresponding to the data signals. Accordingly, an image may be displayed on the display panel DP.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD. For example, the voltage generator 140 may be configured to generate a plurality of voltages by receiving an input voltage from the outside of the display device DD, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In some other embodiments, the first power voltage VDD or the second power voltage VSS may be provided by an external device of the display device DD.

Besides, the voltage generator 140 may generate various suitable voltages. For example, the voltage generator 140 may generate an initialization voltage applied to the sub-pixels SP. For example, a set or predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device DD. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In some other embodiments, at least one of the data driver 130, the voltage generator 140, and the controller 150 may be provided as a component distinguished from (e.g., external to) the driver integrated circuit DIC.

The display device DD may include at least one temperature sensor 160. The temperature sensor 160 may be configured to sense a temperature at the periphery thereof and generate temperature data TEP indicating the sensed temperature. In some embodiments, the temperature sensor 160 may be disposed to be adjacent to the display panel DP and/or the driver integrated circuit DIC.

The controller 150 may control various operations of the display device DD in response to the temperature data TEP. In some embodiments, the controller 150 may adjust the luminance of an image output from the display panel DD in response to the temperature data TEP. For example, the controller 150 may control components such as the data driver 130 and/or the voltage generator 140, thereby adjusting data signals and the first and second power voltages VDD and VSS.

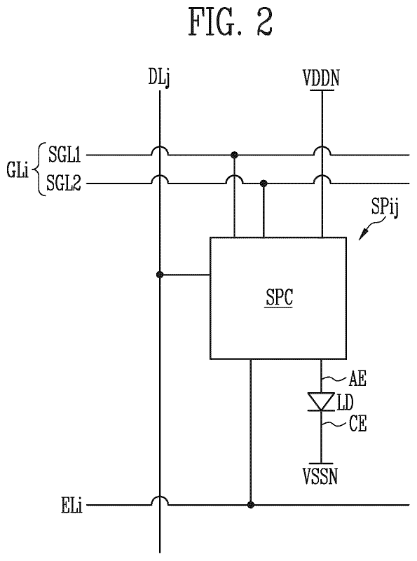

FIG. 2 is a block diagram illustrating one of the sub-pixels shown in FIG. 1, according to some embodiments of the present disclosure. In FIG. 2, a sub-pixel SPij arranged on an ith row (where i is an integer greater than or equal to 1 and smaller than or equal to m) and a jth column (where j is an integer greater than or equal to 1 and smaller than or equal to n) among the sub-pixels SP shown in FIG. 1 is exemplarily illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC. Accordingly, a current may flow from the first power voltage node VDDN to the second power voltage node VSSN. The light emitting element LD may emit light according to an amount of current flowing therethrough.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. In some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In some embodiments, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

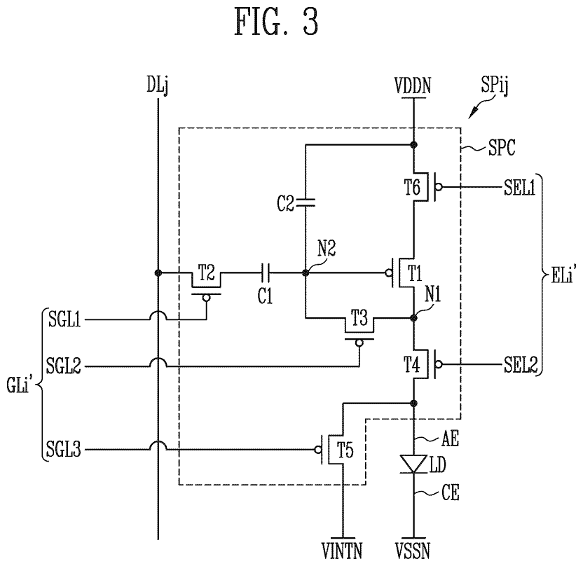

FIG. 3 is a circuit diagram illustrating the sub-pixel shown in FIG. 2, according to some embodiments of the present disclosure.

Referring to FIG. 3, a sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In some embodiments, the initialization voltage may be provided by the voltage generator 140 shown in FIG. 1. In some other embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments of the present disclosure are not limited thereto. The sub-pixel circuit SPC may be implemented as any one of various suitable types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments of the present disclosure are not limited thereto. For example, at least one of the first to sixth transistors T1 to T6 may be replaced with an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. In addition, the first transistor T1 may be turned on according to the voltage of the second node N2, and therefore, a current may flow from the first power voltage node VDDN to a second power voltage node VSSN. The light emitting element LD may emit light according to an amount of the current flowing from the first power voltage node VDDN to the second power voltage node VSSN.

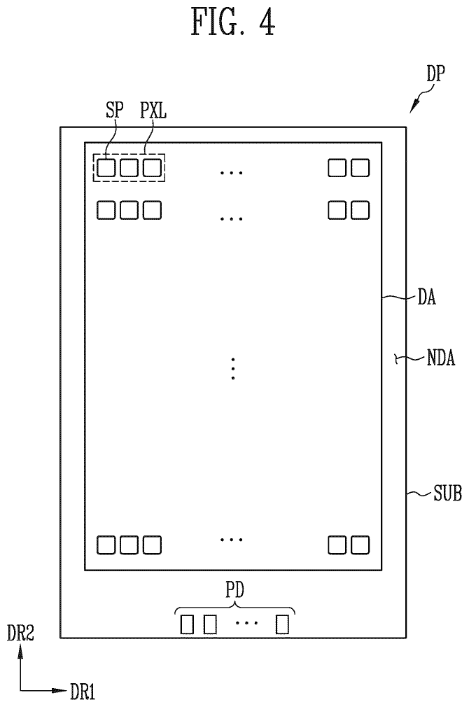

FIG. 4 is a plan view illustrating the display panel shown in FIG. 1, according to some embodiments of the present disclosure.

Referring to FIG. 4, the embodiment of the display panel DP shown in FIG. 1 may include a display area DA and a non-display area NDA. The display panel DP may display an image through the display area DA. The non-display area NDA may be disposed at the periphery of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to the eyes of a user. The sub-pixels SP having a relatively high degree of integration may be desired. In order to increase the degree of integration of the sub-pixels SP, the substrate SUB may be provided as a silicon substrate. The sub-pixels SP and/or the display panel DP may be formed on the substrate SUB as the silicon substrate. The display device DD (see, e.g., FIG. 1) including the display panel DP formed on the substrate SUB as the silicon substrate may be designated as an OLED on Silicon (OLEDOS) display device. However, the display device in accordance with the embodiment of the present disclosure is not limited to only the OLEDOS display device. For example, the display device may be a display device having an Organic Light Emitting Display (OLED) panel using an organic light emitting diode as a light emitting element.

The sub-pixels SP may be disposed in the display area DA on the substrate SUB. The sub-pixels SP may be arranged in a matrix form along a first direction DR1 and a second direction DR2 intersecting the first direction DR1. However, embodiments of the present disclosure are not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction of the pixels, and the second direction DR2 may be a column direction of the pixels.

Two or more sub-pixels among the sub-pixels SP may constitute one pixel PXL. For example, three sub-pixels SP may constitute one pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In some embodiments, the gate driver 120 shown in FIG. 1 is mounted on the display panel DP, and may be disposed in the non-display area NDA. In some other embodiments, the gate driver 120 may be implemented as an integrated circuit distinguished from (e.g., external to) the display panel DP. In some embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device DD (see, e.g., FIG. 1). In some embodiments, voltages and signals, which are used for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In some embodiments, the display area DA may have various suitable shapes. The display area DA may have a closed-loop shape including linear sides and/or curved sides. For example, the display area DA may have shapes such as a polygon, a circle, a semicircle, and an ellipse.

In some embodiments, the display panel DP may have a flat display surface. In some other embodiments, the display panel DP may at least partially have a round display surface. In some embodiments, the display panel DP may be bendable, foldable or rollable. The display panel DP and/or the substrate SUB may include materials having flexibility.

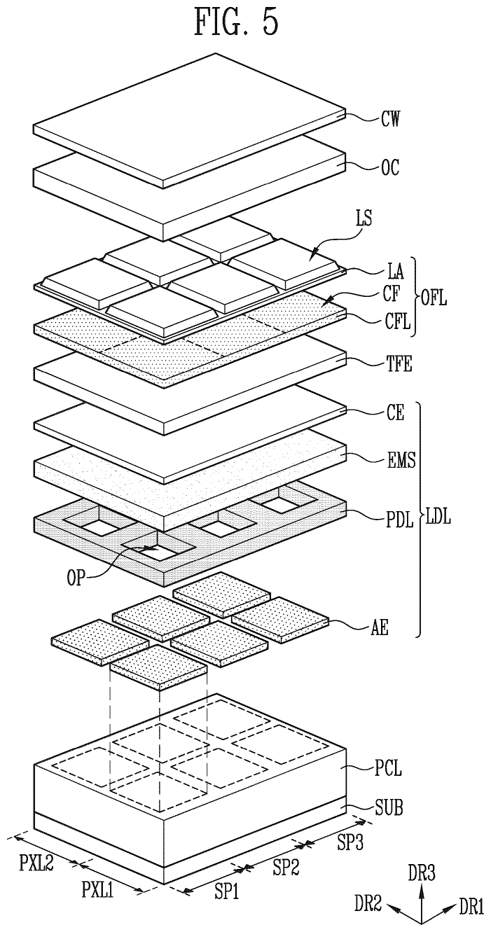

FIG. 5 is an exploded perspective view illustrating a portion of the display panel shown in FIG. 4, according to some embodiments of the present disclosure. In FIG. 5, for clear and brief description, a portion of the display panel DP, which corresponds to two pixels PXL1 and PXL2 among the pixels PXL shown in FIG. 4, may be schematically illustrated. A portion of the display panel DP, which corresponds to the other pixels, may also be configured identically.

Referring to FIGS. 4 and 5, each of first and second pixels PXL1 and PXL2 may include first to third sub-pixels SP1, SP2, and SP3. However, embodiments of the present disclosure are not limited thereto. For example, each of the first and second pixels PXL1 and PXL2 may include four sub-pixels or include two sub-pixels.

In FIG. 5, it may be illustrated that the first to third sub-pixels SP1, SP2, and SP3 may have quadrangular shapes when viewed in a third direction DR3 intersecting the first and second directions DR1 and DR2, and have the same size. However, embodiments of the present disclosure are not limited thereto. The first to third sub-pixels SP1, SP2, and SP3 may be modified to have various suitable shapes.

The display panel DP may include a substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In some other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments of the present disclosure are not limited thereto.

The circuit elements may include a sub-pixel circuit SPC (see, e.g., FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping with the semiconductor portion. In some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines, for example, a gate line, an emission control line, a data line, and the like, which are connected to each of the first to third sub-pixels SP1, SP2, and SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but embodiments of the present disclosure are not limited thereto.

The pixel defining layer PDL may be disposed over the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

In some embodiments, the pixel defining layer PDL may include an inorganic material. The pixel defining layer PDL may include a plurality of stacked inorganic layers. For example, the pixel defining layer PDL may include silicon oxide (SiOₓ), silicon nitride (SiNₓ), and/or the like. In some other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer configured to generate light, an electron transport layer configured to transport electrons, a hole transport layer configured to transport holes, and the like.

In some embodiments, the light emitting structure EMS fills the opening OP of the pixel defining layer PDL, and may be entirely disposed on the top of the pixel defining layer PDL. In other words, the light emitting structure EMS may extend throughout the first to third sub-pixels SP1, SP2, and SP3. At least some of the layers in the light emitting structure EMS may be cut or bent at boundaries between the first to third sub-pixels SP1 to SP3. However, embodiments of the present disclosure are not limited thereto. For example, portions of the light emitting structure EMS, which correspond to the first to third sub-pixels SP1 to SP3, may be separated from each other, and each of the portions may be disposed in the opening OP of the pixel defining layer PDL.

The cathode electrode CE may be disposed on the light emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, gallium tin oxide, and/or the like. In some other embodiments, the cathode electrode CE may include at least one of silver (Ag), magnesium (Mg), or mixtures thereof. However, the material of the cathode electrode CE is not limited thereto.

It may be understood that any one of the anode electrodes AE, a portion of the light emitting structure EMS that overlaps with the anode electrode AE, and a portion of the cathode electrode CE that overlaps with the anode electrode AE, constitute one light emitting element LD (see, e.g., FIG. 2). In other words, each of light emitting elements of the first to third sub-pixels SP1 to SP3 may include one anode electrode AE, a portion of the light emitting structure EMS that overlaps with the anode electrode AE, and a portion of the cathode electrode CE that overlaps with the anode electrode AE. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may be configured to prevent oxygen and/or moisture from infiltrating into the light emitting element layer LDL. In some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), and/or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments of the present disclosure are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the light emitting structure EMS, thereby selectively outputting light of a wavelength band or a color, which corresponds to each sub-pixel SP. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel SP, at least some of the color filters CF may be omitted.

The lens array LA may be disposed on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. In some embodiments, the lenses LS may include an organic material. In some embodiments, the lenses LS may include an acryl-based material. However, the material of the lenses LS is not limited thereto.

In some embodiments, as compared with the opening OP of the pixel defining layer PDL, at least some of the color filters CF of the color filter layer CFL and at least some of the lenses LS of the lens array LS may be shifted in a direction parallel to a plane defined by the first and second directions DR1 and DR2. For example, in a central area of the display area DA, the center of a color filter and the center of a lens may be aligned or overlap with the center of a corresponding opening OP of the pixel defining layer PDL. For example, in the central area of the display area DA, the opening OP of the pixel defining layer PDL may completely overlap with the corresponding color filter of the color filter layer CFL and the corresponding lens of the lens array LA. In an area of the display area DA, which is adjacent to the non-display area NDA, the center of a color filter and the center of a lens may be shifted in a planar direction from the center of an opening OP of the pixel defining layer PDL. For example, in the area of the display area DA, which is adjacent to the non-display area NDA, the opening OP of the pixel defining layer PDL may partially overlap with the corresponding color filter of the color filter layer CFL and the corresponding lens of the lens array LA. Accordingly, in the center of the display area DA, light emitted from the light emitting structure EMS can be effectively output in a normal direction of the display surface. At an outer portion of the display area DA, light emitted from the light emitting structure EMS can be effectively output in a direction inclined by a set or predetermined angle with respect to the normal direction of the display surface.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments of the present disclosure are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index higher than the refractive index of the overcoat layer OC. The cover window CW may include glass, but embodiments of the present disclosure are not limited thereto. For example, the cover window CW may be an encapsulation glass configured to protect components disposed thereunder. In some other embodiments, the cover window CW may be omitted.

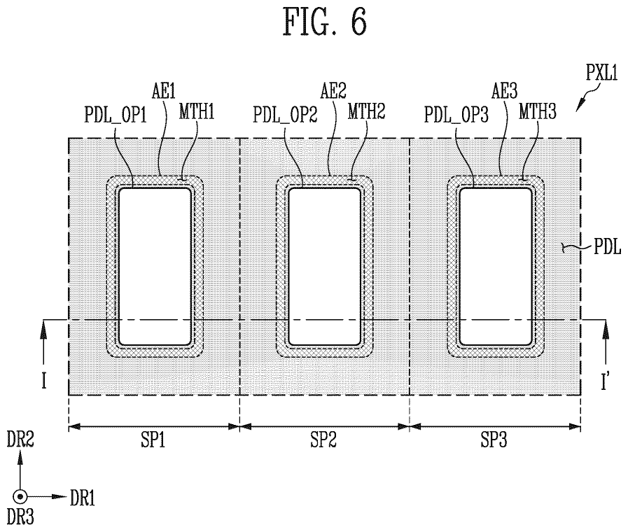

FIG. 6 is a plan view illustrating one of the pixels shown in FIG. 5, according to some embodiments of the present disclosure. In FIG. 6, for clear and brief description, the first pixel PXL1 among the first and second pixels PXL1 and PXL2 shown in FIG. 5 is schematically illustrated. The other pixels may be configured identically to the first pixel PXL1.

Referring to FIGS. 5 and 6, the first pixel PXL1 may include first to third sub-pixels SP1 to SP3 arranged in the first direction DR1.

The first sub-pixel SP1 may include a first anode electrode AE1, a first metal layer MTH1, and a pixel defining layer PDL at the periphery of the first anode electrode AE1.

The pixel defining layer PDL may be formed to surround the first anode electrode AE1. The pixel defining layer PDL may include a first opening PDL_OP1 corresponding to a portion of the first anode electrode AE1, which is exposed from the pixel defining layer PDL. In some embodiments, the first opening PDL_OP1 of the pixel defining layer PDL may define an emission area of the first sub-pixel SP1. The first opening PDL_OP1 of the pixel defining layer PDL may be an area in which light is emitted from a portion of the light emitting structure EMS (see, e.g., FIG. 5), which corresponds to the first sub-pixel SP1.

The pixel defining layer PDL may partially overlap with an edge of the first anode electrode AE1. In addition, the first metal layer MTH1 may be disposed in an area in which the first anode electrode AE1 and the pixel defining layer PDL overlap with each other on a plane. The first metal layer MTH1 may be disposed along the edge of the first anode electrode AE1 to surround the first opening PDL_OP1 of the pixel defining layer PDL.

The second sub-pixel SP2 may include a second anode electrode AE2, a second metal layer MTH2, and the pixel defining layer PDL at the periphery of the second anode electrode AE2.

The pixel defining layer PDL may be formed to surround the second anode electrode AE2. The pixel defining layer PDL may include a second opening PDL_OP2 corresponding to a portion of the second anode electrode AE2, which is exposed from the pixel defining layer PDL. In some embodiments, the second opening PDL_OP2 of the pixel defining layer PDL may define an emission area of the second sub-pixel SP2. The second opening PDL_OP2 of the pixel defining layer PDL may be an area in which light is emitted from a portion of the light emitting structure EMS, which corresponds to the second sub-pixel SP2.

The pixel defining layer PDL may partially overlap with an edge of the second anode electrode AE2. In addition, the second metal layer MTH2 may be disposed in an area in which the second anode electrode AE2 and the pixel defining layer PDL overlap with each other on a plane. The second metal layer MTH2 may be disposed along the edge of the second anode electrode AE2 to surround the second opening PDL_OP2 of the pixel defining layer PDL.

The third sub-pixel SP3 may include a third anode electrode AE3, a third metal layer MTH3, and the pixel defining layer PDL at the periphery of the third anode electrode AE3.

The pixel defining layer PDL may be formed to surround the third anode electrode AE3. The pixel defining layer PDL may include a third opening PDL_OP3 corresponding to a portion of the third anode electrode AE3, which is exposed from the pixel defining layer PDL. In some embodiments, the third opening PDL_OP3 of the pixel defining layer PDL may define an emission area of the third sub-pixel SP3. The third opening PDL_OP3 of the pixel defining layer PDL may be an area in which light is emitted from a portion of the light emitting structure EMS, which corresponds to the third sub-pixel SP3.

The pixel defining layer PDL may partially overlap with an edge of the third anode electrode AE3. In addition, the third metal layer MTH3 may be disposed in an area in which the third anode electrode AE3 and the pixel defining layer PDL overlap with each other on a plane. The third metal layer MTH3 may be disposed along the edge of the third anode electrode AE3 to surround the third opening PDL_OP3 of the pixel defining layer PDL.

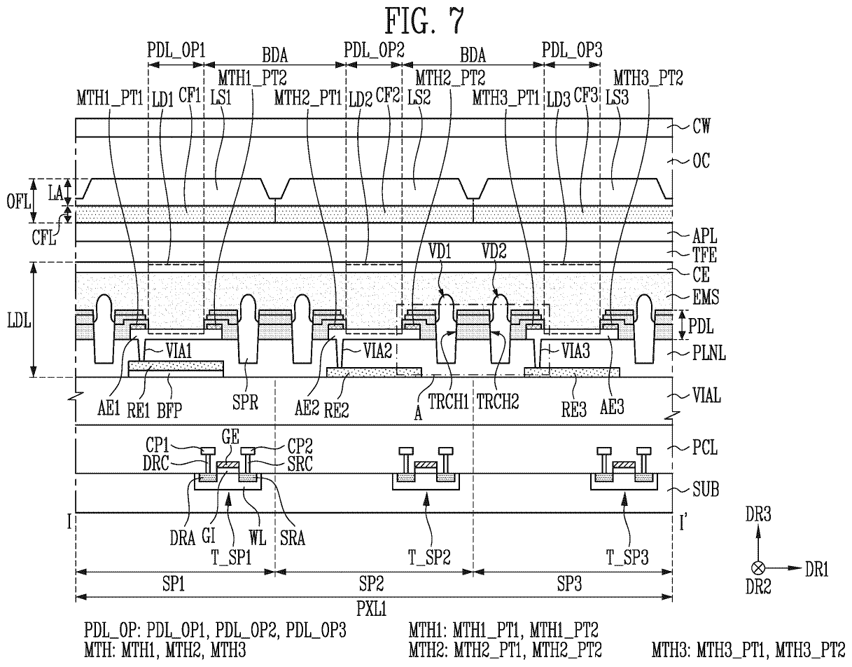

FIG. 7 is a sectional view taken along the line I-I′ shown in FIG. 3, according to some embodiments of the present disclosure.

Referring to FIG. 7, a substrate SUB and a pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see, e.g., FIG. 2) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 7, for the purpose of a clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap with the channel region between the source region SRA and the drain region DRA, and be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and/or the pixel circuit layer PCL may include circuit elements of each of the first to third sub-pixels SP1 to SP3.

A via layer VIAL may be disposed on the pixel circuit layer PCL. The via layer VIAL covers the pixel circuit layer PCL, and may have an entirely flat surface. The via layer VIAL may be configured to planarize step differences on the pixel circuit layer PCL. The via layer VIAL may include silicon oxide (SiOₓ), silicon nitride (SiNₓ), silicon carbon nitride (SiCN), and/or the like, but embodiments of the present disclosure are not limited thereto.

A light emitting element layer LDL may be disposed on the via layer VIAL. The light emitting element layer LDL may include first to third reflective electrodes RE1, RE2, and RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may be in contact with a circuit element disposed in the pixel circuit layer PCL through a via penetrating the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

In some embodiments, a connection electrode may be disposed on the bottom of each of the first to third reflective electrodes RE1 to RE3. The connection electrode may improve an electrical connection characteristic (e.g., may provide a low-impedance electrical path) between a corresponding reflective electrode and a circuit element of the pixel circuit layer PCL. The connection electrode may have a multi-layer structure. The multi-layer structure may include titanium (Ti), titanium nitride (TIN), tantalum nitride (TaN), and the like, but embodiments of the present disclosure are not limited thereto. In some embodiments, a corresponding reflective electrode may be located between multiple layers of the connection electrode.

A buffer pattern BFP may be disposed on the bottom of at least one of the first to third reflective electrodes RE1 to RE3A. The buffer pattern BFP may include an inorganic material such as silicon carbon nitride, but embodiments of the present disclosure are not limited thereto. As the buffer pattern BFP is disposed, a height of the corresponding reflective electrode in a third direction DR3 may be controlled. For example, the buffer pattern BFP may be disposed between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 can effectively and efficiently output light of the corresponding wavelength range.

In FIG. 7, it is illustrated the buffer pattern BFP is provided to the first sub-pixel SP1 and is not provided to the second and third sub-pixels SP2 and SP3. However, embodiments of the present disclosure are not limited thereto. The buffer pattern may be provided even in at least one of the second and third sub-pixels SP2 and SP3, to adjust a resonance distance of the at least one of the second and third sub-pixels SP2 and SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be disposed on the via layer VIAL and the first to third reflective electrodes RE1 to RE3 to planarize step differences between the first to third reflective electrodes RE1 to RE3. The planarization layer PLNL entirely covers the first to third reflective electrodes RE1 to RE3 and the via layer VIAL, and may have a flat surface. In some embodiments, the planarization layer PLNL may be omitted.

The first to third anode electrodes AE1 to AE3 respectively overlapping with the first to third reflective electrodes RE1 to RE3 may be disposed on the planarization layer PLNL. The first to third anode electrodes AE1 to AE3 may be electrically connected to the first to third reflective electrodes RE1 to RE3, respectively. The first anode electrode AE1 may be electrically connected to the first reflective electrode RE1 through a first penetration hole VIA1 penetrating the planarization layer PLNL. The second anode electrode AE2 may be electrically connected to the second reflective electrode RE2 through a second penetration hole VIA2 penetrating the planarization layer PLNL. The third anode electrode AE3 may be electrically connected to the third reflective electrode RE3 through a third penetration hole VIA3 penetrating the planarization layer PLNL.

In some embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO), but embodiments of the present disclosure are not limited thereto. However, the material of the first to third anode electrodes AE1 to AE3 is not limited thereto. For example, the first to third anode electrodes AE1 to AE3 may include titanium nitride.

In some embodiments, the pixel defining layer PDL may be disposed on portions of the first to third anode electrodes AE1 to AE3 and the planarization layer PLNL. The pixel defining layer PDL may include an opening PDL_OP exposing a portion of each of the first to third anode electrodes AE1 to AE3. The opening PDL_OP of the pixel defining layer PDL may define an emission area of each of the first to third sub-pixels SP1 to SP3.

In some embodiments, the pixel defining layer PDL may include a plurality of insulating layers. Each of the plurality of insulating layers may include silicon oxide (SiOₓ), silicon nitride (SiNₓ), and/or the like. For example, the pixel defining layer PDL may include first to third insulating layers which are sequentially stacked, and the first to third insulating layers may include silicon nitride, silicon oxide, and silicon nitride, respectively. However, embodiments of the present disclosure are not limited thereto. The first to third insulating layers may have step difference portions in areas adjacent to the openings PDL_OP. For example, the first to third insulating layers may have step difference portions, each of which has a stepped shape in an area adjacent to a first opening PDL_OP1. The first to third insulating layers may have step difference portions, each of which has a stepped shape in an area adjacent to a second opening PDL_OP2. The first to third insulating layers may have step difference portions, each of which has a stepped shape in an area adjacent to a third opening PDL_OP3.

At least one metal layer MTH may be disposed to overlap with portions of the first to third anode electrodes AE1 to AE3 and the pixel defining layer PDL. The at least one metal layer MTH may be disposed between any one of the first to third anode electrodes AE1 to AE3 and the pixel defining layer PDL.

The at least one metal layer MTH may include first and second portions disposed at the periphery of the openings PDL_OP of the pixel defining layer PDL. The first and second portions may be disposed adjacent to the openings PDL_OP of the pixel defining layer PDL on the corresponding anode electrode. Also, the first and second portions may overlap with the step difference portions of the pixel defining layer PDL. For example, first and second portions MTH1_PT1 and MTH1_PT2 of a first metal layer MTH1 may be disposed at the step difference portions adjacent to the first opening PDL_OP1. First and second portions MTH2_PT1 and MTH2_PT2 of a second metal layer MTH2 may be disposed at the step difference portions adjacent to the second opening PDL_OP2. First and second portions MTH3_PT1 and MTH3_PT2 of a third metal layer MTH3 may be disposed at the step difference portions adjacent to the third opening PDL_OP3.

The at least one metal layer MTH may include a first portion overlapping with the first to third penetration holes VIA1 to VIA3 and a second portion not overlapping with the first to third penetration holes VIA1 to VIA3. For example, the first metal layer MTH1 may be disposed between the first anode electrode AE1 and the pixel defining layer PDL. The first metal layer MTH1 may include the first portion MTH1_PT1 overlapping with the first penetration hole VIA1 and the second portion MTH1_PT2 not overlapping with the first penetration hole VIA1. The second metal layer MTH2 may be disposed between the second anode electrode AE2 and the pixel defining layer PDL. The second metal layer MTH2 may include the first portion MTH2_PT1 overlapping with the second penetration hole VIA2 and the second portion MTH2_PT2 not overlapping with the second penetration hole VIA2. The third metal layer MTH3 may be disposed between the third anode electrode AE3 and the pixel defining layer PDL. The third metal layer MTH3 may include the first portion MTH3_PT1 overlapping with the third penetration hole VIA3 and the second portion MTH3_PT2 not overlapping with the third penetration hole VIA3. Although not shown in FIG. 7, the second portions MTH1_PT2 to MTH3_PT2 may be disposed between the first to third anode electrodes AE1 to AE3 and the first to third reflective electrodes RE1 to RE3.

In some embodiments, the at least one metal layer MTH may include a conductive material. For example, the at least one metal layer MTH may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

In some examples, the at least one metal layer MTH may include low reflective metal materials. For example, the at least one metal layer MTH may include titanium nitride (TiN), titanium (Ti), tantalum (Ta), tantalum nitride (TaN), and/or the like, but the present disclosure is not limited thereto. The at least one metal layer MTH may include a low reflective metal material, to block light emitted in an area adjacent to the openings PDL_OP of the first to third insulating layers.

In other examples, the at least one metal layer MTH may include a material having an absorption coefficient (e.g., a high absorption coefficient). For example, the at least one metal layer MTH may include molybdenum tantalum oxide (MoTaOₓ) (MTO), molybdenum (Mo), tantalum (Ta), manganese (Mn), magnesium (Mg), and/or the like, but the present disclosure is not limited thereto. The at least one metal layer MTH may include a material having an absorption coefficient (e.g., a high absorption coefficient), to absorb light emitted in the area adjacent to the openings PDL_OP of the first to third insulating layers.

A separator SPR may be provided in a boundary area BDA between sub-pixels adjacent to each other. In other words, the separator SPR may be provided in each of the boundary areas between the sub-pixels SP shown in FIG. 4.

The separator SPR may cause a discontinuity to be formed in the light emitting structure EMS in the boundary area BDA. For example, by the separator SPR, the light emitting structure EMS may be cut or bent in the boundary area BDA.

The separator SPR may be provided in or on the pixel defining layer PDL. The pixel defining layer PDL may include one or more trenches TRCH1 and TRCH2 as the separator SPR. In some embodiments, as shown in FIG. 7, the one or more trenches TRCH1 and TRCH2 may penetrate the pixel defining layer PDL, and partially penetrate the via layer VIAL. In some other embodiments, one or more trenches TRCH1 and TRCH2 may penetrate the pixel defining layer PDL and the planarization layer PLNL, and partially penetrate the via layer VIAL. In some other embodiments, one or more trenches TRCH1 and TRCH2 may at least partially penetrate the planarization layer PLNL and/or via layer VIAL, and a portion of the pixel defining layer PDL may be disposed in the one or more trenches TRCH1 and TRCH2.

In FIG. 7, it is illustrated that two trenches TRCH1 and TRCH2 are provided in the boundary area BDA. However, embodiments of the present disclosure are not limited thereto. For example, the pixel defining layer PDL may include one trench in the boundary area BDA. In some examples, the pixel defining layer PDL may include three or more trenches in the boundary area BDA.

Due to first and second trenches TRCH1 and TRCH2, discontinuities such as a first void VD1 and a second void VD2 may be formed in the light emitting structure EMS in the boundary area BDA. Some of a plurality of layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1, SP2, and SP3, may be at least partially separated from each other.

In FIG. 7, it is illustrated that the first and second voids VD1 and VD2 are formed in the light emitting structure EMS in the boundary area BDA. However, this is merely illustrative, and embodiments of the present disclosure are not limited thereto. For example, a concave-shaped valley may be formed in the light emitting structure EMS in the boundary area BDA. The discontinuities formed in the light emitting structure EMS may be variously changed in a suitable manner according to shapes of the first and second trenches TRCH1 and TRCH2.

In some embodiments, the light emitting structure EMS may be formed through a process such as vacuum deposition or inkjet printing. The same materials as the light emitting structure EMS may be located on bottom surfaces adjacent to the via layer VIAL among the first and second trenches TRCH1 and TRCH2.

The separator SPR may be variously modified in a suitable manner such that the light emitting structure EMS can have a discontinuity in the boundary area BDA. In some embodiments, inorganic insulating patterns additionally stacked on the pixel defining layer PDL without the first and second trenches TRCH1 and TRCH2 may be provided in the boundary area BDA. A width of an inorganic insulating pattern at an uppermost portion among the additionally stacked inorganic insulating patterns may be wider than a width of an inorganic insulating pattern disposed immediately under the inorganic insulating pattern at the uppermost portion. For example, in the boundary area BDA, first to third inorganic insulating patterns are sequentially stacked from the pixel defining layer PDL, and the third inorganic insulating pattern at the uppermost portion may have a width wider than a width of the second inorganic insulating layer. For example, the pixel defining layer PDL may have a section having a “T” shape or an “I” shape in the boundary area BDA. According to the shape of the pixel defining layer PDL, the plurality of layers included in the light emitting structure EMS may be partially cut or bent in the boundary area BDA.

The light emitting structure EMS may be disposed on the anode electrodes AE exposed by the openings PDL_OP of the pixel defining layer PDL. The light emitting structure EMS fills the openings PDL_OP of the pixel defining layer PDL, and may be entirely disposed throughout the first to third sub-pixels SP1 to SP3. As described above, the light emitting structure EMS may be at least partially cut or bent by the separator SPR in the boundary area BDA. Accordingly, in an operation of the display panel DP, a current leaked from each of the first to third sub-pixels SP1 to SP3 to a sub-pixel adjacent thereto through layers included in the light emitting structure EMS can be minimized. Thus, first to third light emitting elements LD1 to LD3 can operate with relatively high reliability.

The cathode electrode CE may be disposed over the light emitting structure EMS. The cathode electrode CE may be commonly provided in the first to third sub-pixels SP1 to SP3. The cathode electrode CE may serve as a half mirror which allow light emitted from the light emitting structure EMS to be partially transmitted therethrough and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may constitute a first light emitting element. The second anode electrode AE2, a portion of the light emitting structure EMS, which overlaps with the second anode electrode AE2, and a portion of the cathode electrode CE, which overlaps with the second anode electrode AE2, may constitute a second light emitting element. The third anode electrode AE3, a portion of the light emitting structure EMS, which overlaps with the third anode electrode AE3, and a portion of the cathode electrode CE, which overlaps with the third anode electrode AE3, may constitute a third light emitting element.

An encapsulation layer TFE may be disposed on the cathode electrode CE. The encapsulation layer TFE may prevent oxygen and/or moisture from infiltrating into the light emitting element layer LDL.

An optical functional layer OFL may be disposed on the encapsulation layer TFE. In some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may allow lights having different wavelength ranges to pass therethrough. For example, the first to third color filters CF1 to CF3 may allow light red, green, and blue colors to pass therethrough, respectively.

In some embodiments, the first to third color filters CF1 to CF3 may partially overlap with each other in the boundary area BDA. In some other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting layers LD1 to LD3 along intended paths, thereby improving light emission efficiency.

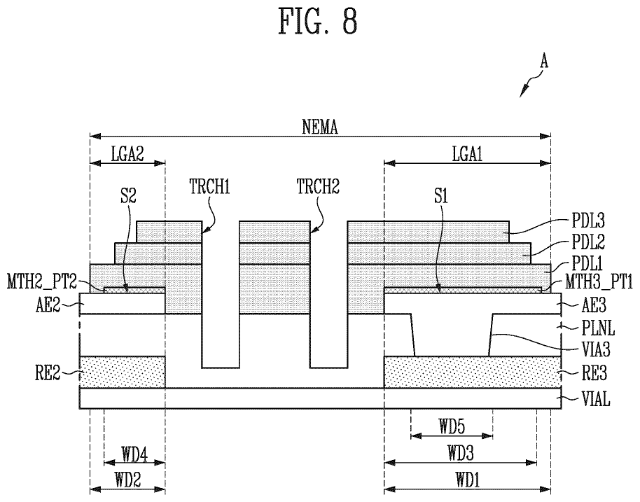

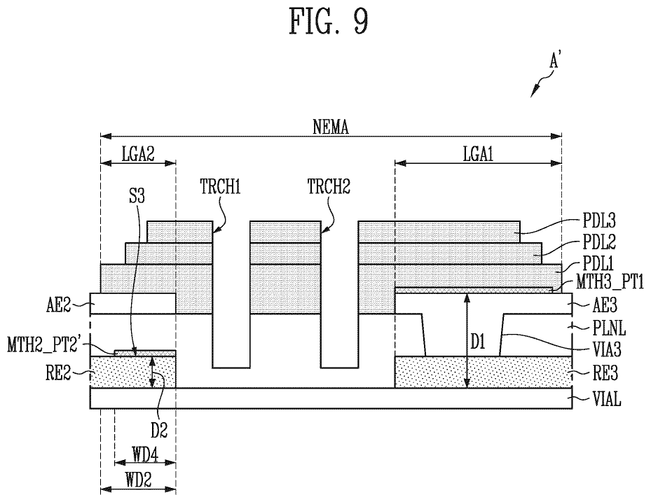

FIGS. 8 and 9 are enlarged view illustrating the portion A shown in FIG. 7, according to some embodiments of the present disclosure. In FIGS. 8 and 9, the pixel defining layer PDL disposed between the second sub-pixel SP2 and the third sub-pixel SP3, which are shown in FIG. 7, is mainly illustrated. In addition, the second portion MTH2_PT2 of the second metal layer MTH2 and the first portion MTH3_PT1 of the third metal layer MTH3 are illustrated.

Referring to FIGS. 7 and 8, the at least one metal layer MTH may include first and second portions which are arranged in the first direction DR1.

In some embodiments, the third metal layer MTH3 may include the first portion MTH3_PT1 overlapping with the third penetration hole VIA3 connecting the third anode electrode AE3 and the third reflective electrode RE3 to each other. The first portion MTH3_PT1 may be disposed between a first insulating layer PDL1 adjacent to the planarization layer PLNL among first to third insulating layers PDL1 to PLD3 and the third anode electrode AE3. Also, the first portion MTH3_PT1 may be disposed to be in contact with a top surface S1 of the third anode electrode AE3.

The first portion MTH3_PT1 may be disposed in a first area LGA1 in which the first insulating layer PDL1 and the third anode electrode AE3 overlap with each other. The first area LGA1 may be an area having step difference portions as a portion of a non-emission area NEMA between the second and third openings PDL_OP2 and PDL_OP3 of the pixel defining layer PDL. The first portion MTH3_PT1 may be disposed to overlap with a portion of the first area LGA1. A width WD3 of the first portion MTH3_PT1 may be narrower than or equal to a width WD1 of the first area LGA1 in which the first insulating layer PDL and the third anode electrode AE3 overlap with each other. Also, the first portion MTH3_PT1 may be disposed to cover the third penetration hole VIA3. The width WD3 of the first portion MTH3_PT1 may be wider than or equal to a width WD5 of the third penetration hole VIA3. In FIG. 8, the first portion MTH3_PT1 of the third metal layer MTH3 is described as an example. However, the first portion MTH1_PT1 of the first metal layer MTH1 and the first portion MTH2_PT1 of the second metal layer MTH2 may also be configured identically to the first portion MTH3_PT of the third metal layer MTH3.

In some embodiments, the second metal layer MTH2 may include the second portion MTH2_PT2 disposed in the same layer as the first portion MTH3_PT of the third metal layer MTH3. Unlike the first portion MTH3_PT1, the second portion MTH2_PT2 may not overlap with the second penetration hole VIA2 (see, e.g., FIG. 7) connecting the second anode electrode AE2 and the second reflective electrode RE2 to each other. The second portion MTH2_PT2 may be disposed between the first insulating layer PDL1 adjacent to the planarization layer PLNL among the first to third insulating layers PDL1 to PDL3 and the second anode electrode AE2. Also, the second portion MTH2_PT2 may be disposed to be in contact with a top surface S2 of the second anode electrode AE2.

The second portion MTH2_PT2 may be disposed in a second area LGA2 in which the first insulating layer PDL1 and the second anode electrode AE2 overlap with each other. The second area LGA2 may be an area having step difference portions as a portion of the non-emission area NEMA between the second and third openings PDL_OP2 and PDL_OP3 of the pixel defining layer PDL. The second area LGA2 may be spaced apart from the first area LGA1 with the first and second trenches TRCH1 and TRCH2 interposed therebetween, which penetrate the pixel defining layer PDL and partially penetrate the planarization layer PLNL. The second portion MTH2_PT2 may be disposed to overlap with a portion of the second area LGA2. A width WD4 of the second portion MTH2_PT2 may be narrower than or equal to a width WD2 of the second area LGA2 in which the first insulating layer PDL1 and the second anode electrode AE2 overlap with each other. In FIG. 8, the second portion MTH2_PT2 of the second metal layer MTH2 is described as an example. However, the second portion MTH1_PT2 of the first metal layer MTH1 and the second portion MTH3_PT2 of the third metal layer MTH3 may also be configured identically to the second portion MTH2_PT2 of the second metal layer MTH2.

Referring to FIG. 9, the at least one metal layer MTH may include first and second portions spaced apart from the via layer VIAL at different distances. Descriptions of the first portion MTH3_PT1 of the third metal layer MTH3 may be the same as the embodiment of FIG. 8. In relation to the embodiments shown in FIG. 8, overlapping descriptions will be omitted, and portion different from the portions of the above-described embodiment will be mainly described.

Referring to FIGS. 7 and 9, the at least one metal layer MTH may include a first metal layer spaced apart from via layer VIAL by a first distance D1 and a second metal layer spaced apart from the via layer VIAL by a second distance D2. The first metal layer may be provided as the first portion MTH3_PT1 of the third metal layer MTH3, and the second metal layer may be provided as a second portion MTH2_PT2′ of the second metal layer MTH2. The first and second distances D1 and D2 may be different from each other.

In some embodiments, the second metal layer MTH2 may include the second portion MTH2_PT2′ disposed in a layer different from a layer in which the first portion MTH3_PT1 of the third metal layer MT3H is disposed. The second portion MTH2_PT2′ may be disposed between the second anode electrode AE2 and the second reflective electrode RE2. The second portion MTH2_PT2′ may be disposed to face the second electrode AE2 with the planarization layer PLNL interposed therebetween. Also, the second portion MTH2_PT2′ may be disposed to be in contact with a top surface S3 of the second reflective electrode RE2.

The second portion MTH2_PT2′ may be disposed in a second area LGA2 in which the first insulating layer PDL1 and the second anode electrode AE2 overlap with each other. The second area LGA2 may be an area having step difference portions as a portion of the non-emission area NEMA between the second and third openings PDL_OP2 and PDL_OP3 of the pixel defining layer PDL. The second portion MTH2_PT2′ may be disposed to overlap with a portion of the second area LGA2. A width WD4 of the second portion MTH2_PT2′ may be narrower than or equal to a width WD2 of the second area LGA2 in which the first insulating layer PDL1 and the second anode electrode AE2 overlap with each other. In FIG. 9, the second portion MTH2_PT2′ of the second metal layer MTH2 is described as an example. However, the second portion MTH1_PT2 of the first metal layer MTH1 and the second portion MTH3_PT2 of the third metal layer MTH3 may also be configured identically to the second portion MTH2_PT2′ of the second metal layer MTH2.

As such, the at least one metal layer MTH is disposed in an area in which the first to third anode electrodes AE1 to AE3 and the step difference portions of the pixel defining layer PDL overlap with each other, so that light emitted in an area in which the openings PDL_OP of the pixel defining layer PDL are adjacent to each other can be effectively blocked. When light reflected by the third reflective electrode RE3 in the first area LGA1 is emitted through the pixel defining layer PDL or when light reflected by the second reflective electrode RE2 in the second area LGA2 is emitted through the pixel defining layer PDL, color mixture between adjacent sub-pixels may occur. In accordance with the embodiment of the present disclosure, due to the second portion MTH2_PT2 of the second metal layer MTH2 and the first portion MTH3_PT1 of the third metal layer MTH3, light reflected by the second and third reflective electrodes RE2 and RE3 in the first and second areas LGA1 and LGA2 or at the periphery thereof can be blocked from being emitted through the pixel defining layer PDL. Accordingly, the occurrence of color mixture between adjacent sub-pixels can be prevented, and thus a color reproduction range can be further improved.

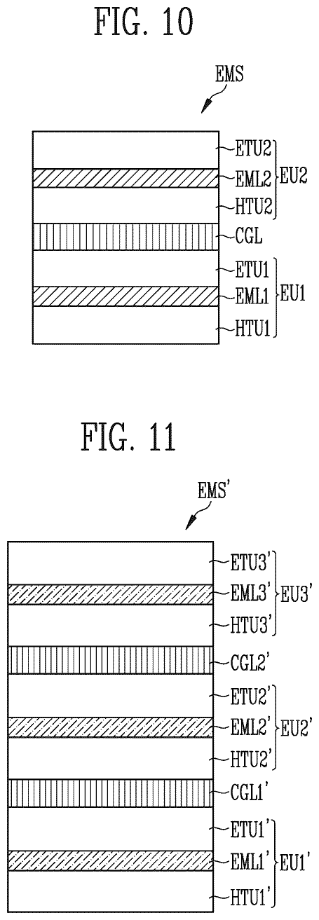

FIGS. 10 and 11 are sectional views illustrating a light emitting structure included in any one of the first to third light emitting elements shown in FIG. 6, according to some embodiments of the present disclosure.

Referring to FIG. 10, the light emitting structure EMS may have a tandem structure in which first and second light emitting units EU1 and EU2 are stacked. The light emitting structure EMS may be configured substantially identically in each of the first to third light emitting elements LD1 to LD3 shown in FIG. 7.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if desired. The first and second hole transport units HTU1 and HTU2 may have the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if desired. The first and second electron transport units ETU1 and ETU2 may have the same configuration or have different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In some embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments of the present disclosure are not limited thereto.

In some embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. In some embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further disposed between the first and second sub-light emitting layers.

In some other embodiments, the first light emitting layer EML1 and the second light emitting layer EML2 may generate light of the same color.

The light emitting structure EMS may be formed through a process such as vacuum deposition or inkjet printing, but embodiments of the present disclosure are not limited thereto.

Referring to FIG. 11, a light emitting structure EMS' may a tandem structure in which first to third light emitting units EU1′, EU2′, and EU3′ are stacked. The light emitting structure EMS' may be configured substantially identically in each of the first to third light emitting elements LD1 to LD3 shown in FIG. 7.

Each of the first to third light emitting units EU1′ to EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and an electron blocking layer, and the like, if desired. The first to third hole transport units HTU1′ to HTU3′ may have the same configuration or have different configurations.

Each of the first to third electron transport units ETU1′ to ETU3′ may include at least one of an electron injection layer and an electron transport layer, and further include an electron buffer layer, a hole blocking layer, and the like, if desired. The first to third electron transport units ETU1′ to ETU3′ may have the same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In some embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In some other embodiments, at least two light emitting layers among the first to third light emitting layers EML1′ to EML3′ may generate light of the same color.

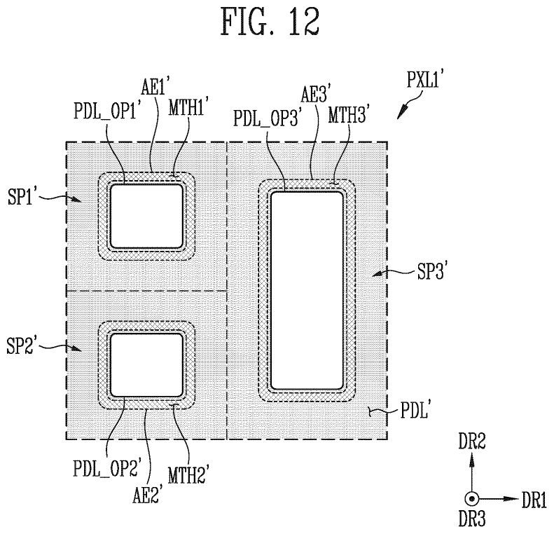

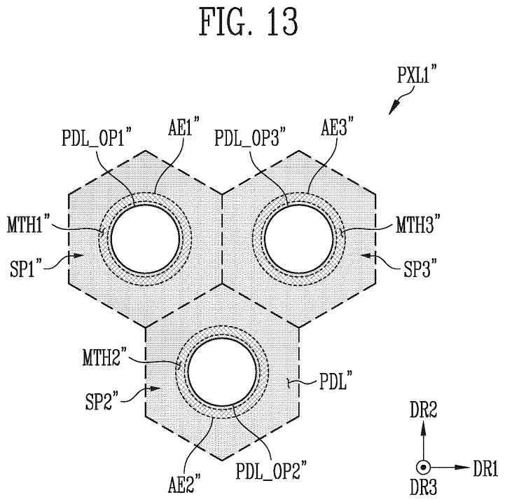

FIGS. 12 and 13 are plan views illustrating one of the pixels shown in FIG. 4, according to some embodiments of the present disclosure.

Referring to FIG. 12, a first pixel PXL1′ may include first to third sub-pixels SP1′ to SP3′.

The first sub-pixel SP1′ may include a first anode electrode AE1′, a first metal layer MTH1′, and a pixel defining layer PDL′ at the periphery of the first anode electrode AE1′. The pixel defining layer PDL′ may include a first opening PDL_OP1′ corresponding to a portion of the first anode electrode AE1′, which is exposed from the pixel defining layer PDL′. In addition, the first metal layer MTH1′ may be disposed in an area in which the first anode electrode AE1′ and the pixel defining layer PDL′ overlap with each other.

The second sub-pixel SP2′ may include a second anode electrode AE2′, a second metal layer MTH2′, and the pixel defining layer PDL′ at the periphery of the second anode electrode AE2′. The pixel defining layer PDL′ may include a second opening PDL_OP2′ corresponding to a portion of the second anode electrode AE2′, which is exposed from the pixel defining layer PDL′. In addition, the second metal layer MTH2′ may be disposed in an area in which the second anode electrode AE2′ and the pixel defining layer PDL′ overlap with each other.

The third sub-pixel SP3′ may include a third anode electrode AE3′, a third metal layer MTH3′, and the pixel defining layer PDL′ at the periphery of the third anode electrode AE3′. The pixel defining layer PDL′ may include a third opening PDL_OP3′ corresponding to a portion of the third anode electrode AE3′, which is exposed from the pixel defining layer PDL′. In addition, the third metal layer MTH3′ may be disposed in an area in which the third anode electrode AE3′ and the pixel defining layer PDL′ overlap with each other.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have an area larger than an area of the first sub-pixel SP1′, and the third sub-pixel SP3′ may have an area larger than the area of the second sub-pixel SP2′. Accordingly, the second anode electrode AE2′ may have an area larger than an area of the first anode electrode AE1′, and the third anode electrode AE3′ may have an area larger than the area of the second anode electrode AE2′. However, embodiments of the present disclosure are not limited thereto. For example, the first and second sub-pixels SP1′ and SP2′ may substantially have the same area, and the third sub-pixel SP3′ may have an area larger than the area of each of the first and second sub-pixels SP1′ and SP2′. As such, the areas of the first to third sub-pixels SP1′ to SP3′ may be variously modified as desired.

Referring to FIG. 13, a first sub-pixel SP1″ may include a first anode electrode AE1″, a first metal layer MTH1″, and a pixel defining layer PDL″ at the periphery of the first anode electrode AE1″. The pixel defining layer PDL″ may include a first opening PDL_OP1″. In addition, the first metal layer MTH1″ may be disposed in an area in which the first anode electrode AE1″ and the pixel defining layer PDL″ overlap with each other.

A second sub-pixel SP2″ may include a second anode electrode AE2″, a second metal layer MTH2″, and the pixel defining layer PDL″ at the periphery of the second anode electrode AE2″. The pixel defining layer PDL″ may include a second opening PDL_OP2″. In addition, the second metal layer MTH2″ may be disposed in an area in which the second anode electrode AE2″ and the pixel defining layer PDL″ overlap with each other.

A third sub-pixel SP3″ may include a third anode electrode AE3″, a third metal layer MTH3″, and the pixel defining layer PDL″ at the periphery of the third anode electrode AE3″. The pixel defining layer PDL″ may include a third opening PDL_OP3″. In addition, the third metal layer MTH3″ may be disposed in an area in which the third anode electrode AE3″ and the pixel defining layer PDL″ overlap with each other.

The first to third sub-pixels SP1″ to SP3″ may have polygonal shapes when viewed in the third direction DR3. For example, the shapes of the first to third sub-pixels SP1″ to SP3″ may be hexagonal shapes as shown in FIG. 13.

The first to third anode electrodes AE1″ to AE3″ may have circular shapes when viewed in the third direction DR3. However, embodiments of the present disclosure are not limited thereto. For example, each of the first to third anode electrodes AE1″ to AE3″ may have a polygonal shape.

The first and third sub-pixels SP1″ and SP3″ may be arranged in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 6, 12, and 13, are merely illustrative, and embodiments of the present disclosure are not limited thereto. Each pixel may include two or more sub-pixels, and the sub-pixels may be arranged in various suitable manners. Each of the sub-pixels may have various suitable shapes, and an emission area EMA of the sub-pixel may have various suitable shapes.

In the display device in accordance with the embodiments of the present disclosure, at least one metal layer MTH is disposed in an area in which the first to third anode electrodes AE1 to AE3 and step difference portions of the pixel defining layer PDL overlap with each other, so that light emitted in an area adjacent to the openings PDL_OP of the pixel defining layer PDL can be more effectively blocked. Accordingly, the occurrence of color mixture between adjacent sub-pixels is prevented, so that the color reproduction range can be further improved (e.g., increased).

In accordance with the present disclosure, there can be provided a display device having improved (e.g., increased) efficiency and a method of manufacturing the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various suitable changes in form and details may be made without departing from the spirit and scope of the present disclosure as defined by the following claims and equivalents thereof.

What is claimed is:

1. A display device comprising:
a base layer;
a reflective electrode on the base layer;
a planarization layer over the reflective electrode, the planarization layer having a flat top surface;
an anode electrode on the planarization layer;
a pixel defining layer on a portion of the anode electrode and the planarization layer;
a light emitting structure on the anode electrode and the pixel defining layer;
a cathode electrode on the light emitting structure; and
a metal layer overlapping with the portion of the anode electrode and the pixel defining layer,
wherein the planarization layer comprises a penetration hole connecting the anode electrode and the reflective electrode to each other,
wherein the metal layer comprises a first portion overlapping with the penetration hole and a second portion not overlapping with the penetration hole, and
wherein the first portion is between the anode electrode and the pixel defining layer.

2. The display device of claim 1, wherein the first portion is in contact with a top surface of the anode electrode that is adjacent to the cathode electrode.

3. The display device of claim 1, wherein the second portion is between the anode electrode and the pixel defining layer.

4. The display device of claim 3, wherein the second portion is in contact with a top surface of the anode electrode that is adjacent to the cathode electrode.

5. The display device of claim 3, wherein the pixel defining layer comprises a plurality of insulating layers, and
wherein the second portion is between the anode electrode and one of the plurality of insulating layers that is adjacent to the planarization layer.

6. The display device of claim 5, wherein the second portion has a width narrower than a width of a first area in which the insulating layer and the anode electrode overlap with each other.

7. The display device of claim 1, wherein the pixel defining layer comprises a plurality of insulating layers, and
wherein the first portion is between the anode electrode and one of the plurality of insulating layers that is adjacent to the planarization layer.

8. The display device of claim 7, wherein the first portion has a width narrower than a width of a second area in which the insulating layer and the anode electrode overlap with each other.

9. The display device of claim 8, wherein the first portion has a width wider than a width of the penetration hole.

10. The display device of claim 1, wherein the metal layer comprises:
a first metal layer spaced apart from the base layer by a first distance; and
a second metal layer spaced apart from the base layer by a second distance different from the first distance, and
wherein the first metal layer is provided as the first portion, and
wherein the second metal layer is provided as the second portion.

11. The display device of claim 1, wherein the second portion is between the anode electrode and the reflective electrode.

12. The display device of claim 11, wherein the second portion is in contact with the reflective electrode.

13. The display device of claim 11, wherein the second portion is positioned to face the anode electrode with the planarization layer interposed therebetween.

14. The display device of claim 11, wherein the second portion has a width narrower than a width of a first area in which the portion of the anode electrode and the pixel defining layer overlap with each other.

15. The display device of claim 1, wherein the first and second portions comprise a conductive material.

16. The display device of claim 1, wherein the light emitting structure comprises at least two light emitting units that are sequentially stacked and at least one charge generation layer between the light emitting units, and
wherein each of the at least two light emitting units comprises a light emitting layer.
